(19) United States
(12) Patent Application Publication
(10) Pub. No.: US 2016/0372343 A1
(43) Pub. Date: Dec. 22, 2016

(54) SUBSTRATE SUPPORT DEVICE, SUBSTRATE SUPPORT METHOD AND VACUUM DRYING EQUIPMENT

(71) Applicants: BOE TECHNOLOGY GROUP CO., LTD, Beijing (CN); HEFEI BOE OPTOELECTRONICS TECHNOLOGY CO., LTD., Hefei, Anhui (CN)

(72) Inventors: Man WANG, Beijing (CN); Yuman ZHAI, Beijing (CN)

(21) Appl. No.: 14/899,913

(22) PCT Filed: Jun. 18, 2015
(86) PCT No.: PCT/CN2015/081732

§ 371 Date: Dec. 18, 2015

(30) Foreign Application Priority Data
Jan. 12, 2015 (CN) 201510015104.4

(51) Int. Cl. H01L 21/67; F26B 5/04; H01L 21/687

(52) U.S. Cl. CPC H01L 21/67034; H01L 21/6875; H01L 21/68735; H01L 21/68742; F26B 5/04

(57) ABSTRACT

The embodiments of the invention disclose a substrate support device, a support method and a vacuum drying equipment. The substrate support device comprises a fixed mechanism including a table board arranged with a plurality of via-holes, and a lifting mechanism including a plurality of flat plate parts corresponding to the via-holes, the plurality of flat plate parts being capable of moving into corresponding via-holes respectively to form a support surface for supporting the substrate, together with the table board, and further capable of moving to positions above the corresponding via-holes. In the embodiments of the invention, the substrate is always placed on the flat table board throughout the drying process by cooperating the fixed mechanism and the lifting mechanism. Thus, the contact mode between the substrate and the substrate support device is changed from a point contact to a surface contact, thereby reducing the risk of the product display deficiency.

### CROSS-REFERENCES TO RELATED APPLICATIONS

This patent application claims priority of Chinese Patent Application No. 201510015104.4, filed on Jan. 12, 2015, the entire content of which is incorporated by reference herein.

### FIELD OF THE INVENTION

The present invention relates to the technical field of display panel manufacturing, and particularly to a substrate support device, a substrate support method and a vacuum drying equipment comprising the substrate support device.

### BACKGROUND

In the manufacturing process of the array substrate and the colour-film substrate, most of the film layers concern the coating, exposing and developing technologies of the photoresist. After the photoresist is coated, a vacuum drying treatment shall be performed on the film layer. Namely, a solvent volatilization shall be carried out under the conditions of a room temperature and an atmospheric pressure close to 0 Pa, so as to keep certain uniformity and hardness of the film layer, and prepare for the subsequent exposing and developing technologies.

FIG. 1 illustrates the internal structure of a chamber of the existing vacuum drying equipment. As illustrated in FIG. 1, the bottom of a chamber 1 is arranged with a certain number of mobile support pins 2 which are fixed by way of magnet adsorption. FIGS. 2a to 2f illustrate an operation flow of the existing vacuum drying equipment.

Firstly, as illustrated in FIG. 2a, a manipulator 3 conveys a substrate 4 coated with a film layer on its surface into the chamber 1; next, as illustrated in FIG. 2b, the manipulator 3 descends so that the substrate 4 is placed on the support pins 2 and supported by them; next, as illustrated in FIG. 2c, the manipulator 3 withdraws and a vacuum drying treatment is performed inside the chamber 1; next, as illustrated in FIGS. 2d and 2e, after the drying is finished, the manipulator 3 moves into the gap between the support pins 2 to raise the substrate 4; and finally, as illustrated in FIG. 2f, the manipulator 3 withdraws and the substrate 4 is taken out.

In the above support manner, the support pins 2 must be located in the non-display area of the substrate 4 during the support. As illustrated in FIGS. 3 and 4, the support pins 2 are distributed around the display area of the substrate 4. This is because the position on the substrate 4 contacted with the support pin 2 will be pushed up to form a small protuberance as illustrated in FIG. 5. A film layer 5 coated on the surface of the substrate 4 will flow so that the thickness of the film at the protuberance gets thinner than the surrounding area. In the drying process, mura will be formed because the film thickness is not uniform. When the vacuum drying is finished, the fluidity is greatly reduced since most solvent in the film layer 5 has been volatilized. Thus, the small protuberance formed by the support pin 2 cannot be recovered. That is to say, the display mura is still existed, and the display effect is affected.

In the actual production, different substrates have different layouts, thus the support pins are also distributed differently. When the product model is changed, the operator has to adjust the positions of the support pins to avoid the display area of the substrate. In the adjustment process of the support pins, dusts and particles will be easily introduced. Meanwhile, the wrong position of the support pin caused by any human error also degrades display quality of the product. In addition, the distribution of the support pins depends on the layout of the substrate, so the contact points of the support pins must be considered adequately during the substrate design. While it is ensured that the distribution of the contact points is relatively uniform, the support pins shall also be prevented from interfering with the action of the manipulator. As a result, not only the substrate design is more difficult, but also the substrate utilization is limited.

### BRIEF SUMMARY OF THE DISCLOSURE

The object of the embodiment of the present invention is to provide a substrate support device, a support method and a vacuum drying equipment, so as to solve the problems of complex design and operation and high risk of deficiency of the existing support device.

As a first aspect of the present invention, there is provided a substrate support device for a vacuum drying equipment. The substrate support device comprises a fixed mechanism that includes a table board arranged with a plurality of via-holes, and a lifting mechanism that includes a plurality of flat plate parts corresponding to the via-holes, the plurality of flat plate parts being capable of moving into corresponding via-holes respectively to form a support surface for supporting the substrate, together with the table board, and further capable of moving to positions above the corresponding via-holes.

In an embodiment, the table board comprises a plurality of sub-table boards, and a strip gap is formed between every two adjacent sub-table boards to serve as a via-hole.

In an embodiment, the via-hole has a closed shape.

In an embodiment, the closed shape is rectangular or circular.

In an embodiment, the plurality of via-holes are uniformly distributed in the table board, and the shape of the flat plate part is matched with that of the via-hole at corresponding position.

In an embodiment, the shape of the flat plate part comprises a rectangle or a circle.

In an embodiment, the lifting mechanism comprises a lifting driving unit, a plurality of support rods and a plurality of support pillars, each of the support rods is arranged with a support pillar for supporting the flat plate part, and the lifting driving unit is arranged to drive the support rods to rise and descend.

In an embodiment, the lifting mechanism further comprises a connection rod for connecting the plurality of support rods together, and the connection rod is connected to an output shaft of the lifting driving unit.

In an embodiment, each of the support pillars supports one of the flat plate parts separately.

In an embodiment, several of the support pillars support one of the flat plate parts together.

As a second aspect of the present invention, there is further provided a support method using the substrate support device, comprising:

when drying the substrate, moving the flat plate part of the lifting mechanism into the via-hole of the fixed mechanism, so as to support the substrate together with the table board of the fixed mechanism.

Preferably, the support method comprises:

before drying the substrate, moving the flat plate part of the lifting mechanism to a position above the via-hole of the fixed mechanism, and placing the substrate on the flat plate part;

when drying the substrate, lowering the flat plate part into the via-hole, so that the flat plate part is flushed with the table board of the fixed mechanism; and

after drying the substrate, raising the flat plate part to a position above the via-hole so as to take out the substrate.

In an embodiment, the support method comprises:

before drying the substrate, moving the flat plate part of the lifting mechanism to a position below the via-hole of the fixed mechanism, and placing the substrate on the table board;

when drying the substrate, raising the flat plate part into the via-hole, so that the flat plate part is flushed with the table board of the fixed mechanism; and

after drying the substrate, lowering the flat plate part to a position below the via-hole so as to take out the substrate.

As a third aspect of the present invention, there is further provided a vacuum drying equipment, comprising the aforementioned substrate support device.

According to the embodiments of the present invention, the substrate is always placed on the flat table board throughout the drying process by way of cooperating the fixed mechanism 6 and the lifting mechanism 7. Thus, as compared with the prior art, the contact mode between the substrate and the substrate support device is changed from a point contact to a surface contact, thereby reducing the risk of the product display deficiency. In addition, it is unnecessary to consider the substrate layout for different models of products. When the product model is changed, the support device needs not to be adjusted. In conclusion, the present invention has the following advantages:

1. when the product model is changed, it is unnecessary to adjust the support part, thus the personal workload is reduced;

2. avoiding the risk that any person introduces the particles into the equipment when adjusting the support device, and preventing the display deficiency due to a wrong support part caused by the human error, thereby improving the product quality; and

3. In the aspect of the product design, since the contact mode is changed from the point contact to the surface contact, the positions of the contact points need not to be considered, thus the substrate can be sufficiently utilized, and the design difficulty of the device is decreased.

### BRIEF DESCRIPTION OF THE DRAWINGS

The preferred embodiments of the present invention are further understood with reference to the accompanying drawings. To be noted, the accompanying drawings constitute a part of the Specification and are used for explaining the present invention together with the following specific embodiments, rather than limit the present invention, in which:

FIG. 1 is a schematic diagram illustrating the internal structure of a chamber of an existing vacuum drying equipment;

FIGS. 2a to 2f are flowcharts illustrating the operation process of the existing vacuum drying equipment;

FIG. 3 is a schematic diagram illustrating a distribution of support rods in the prior art;

FIG. 4 is a schematic diagram illustrating another distribution of support rods in the prior art;

FIG. 5 is a schematic diagram illustrating mura formed by the support pins;

FIG. 6 is a schematic diagram of a substrate support device according to a first embodiment of the present invention;

FIGS. 7a to 7c respectively are a side view, a top view and a bottom view of a fixed mechanism of the substrate support device as illustrated in FIG. 6;

FIGS. 8a to 8c respectively are a side view, a top view and a bottom view of a lifting mechanism of the substrate support device as illustrated in FIG. 6;

FIGS. 9a to 9c respectively are a side view, a top view and a bottom view of a combination of the fixed mechanism and the lifting mechanism of the substrate support device as illustrated in FIG. 6;

FIGS. 10a to 10h respectively are flowcharts of the working process of the substrate support device as illustrated in FIG. 6;

FIG. 11 is a schematic diagram of a substrate support device according to a second embodiment of the present invention;

FIGS. 12a to 12c respectively are a side view, a top view and a bottom view of a fixed mechanism of the substrate support device as illustrated in FIG. 11;

FIGS. 13a to 13c respectively are a side view, a top view and a bottom view of a lifting mechanism of the substrate support device as illustrated in FIG. 11;

FIGS. 14a to 14c respectively are a side view, a top view and a bottom view of a combination of the fixed mechanism and the lifting mechanism of the substrate support device as illustrated in FIG. 11; and

FIGS. 15a to 15h respectively are flowcharts of the working process of the substrate support device as illustrated in FIG. 11.

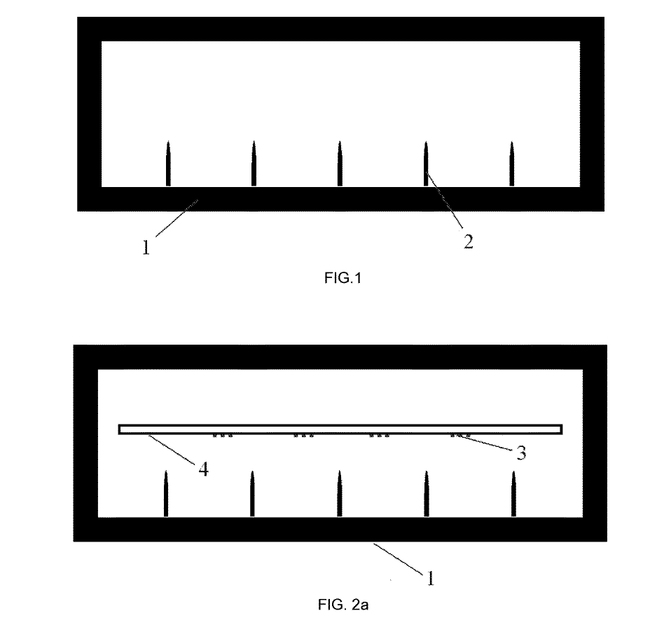

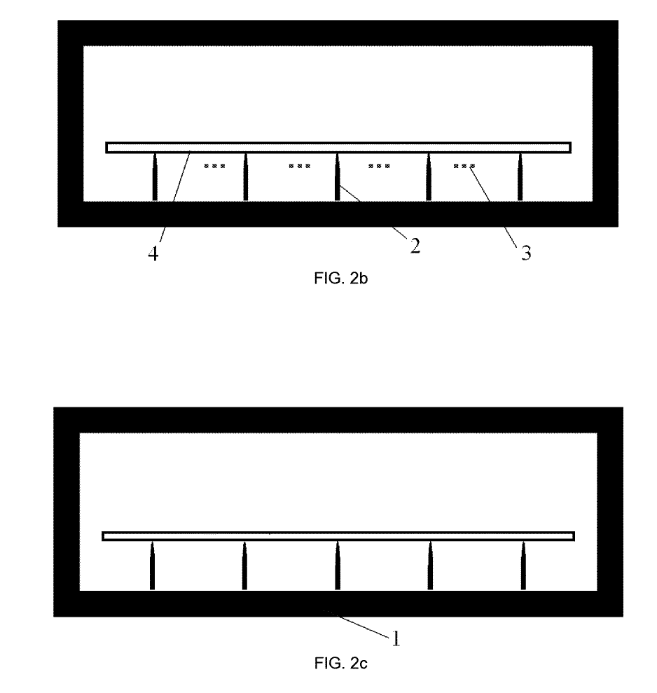

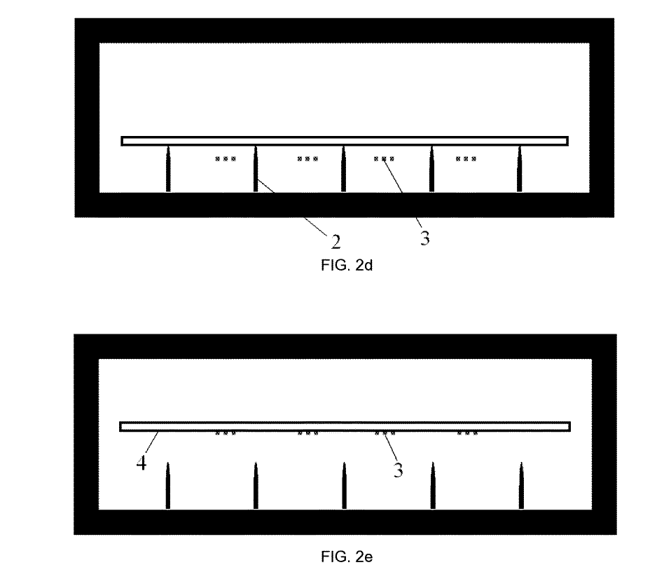

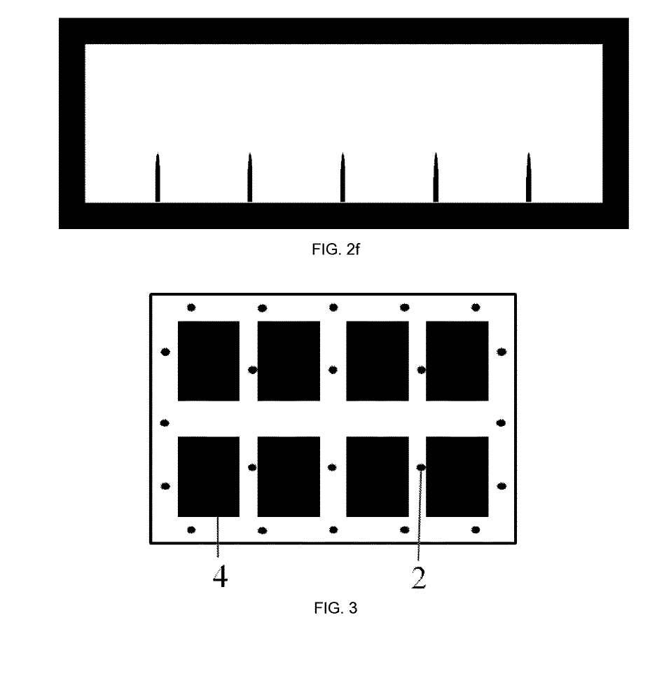

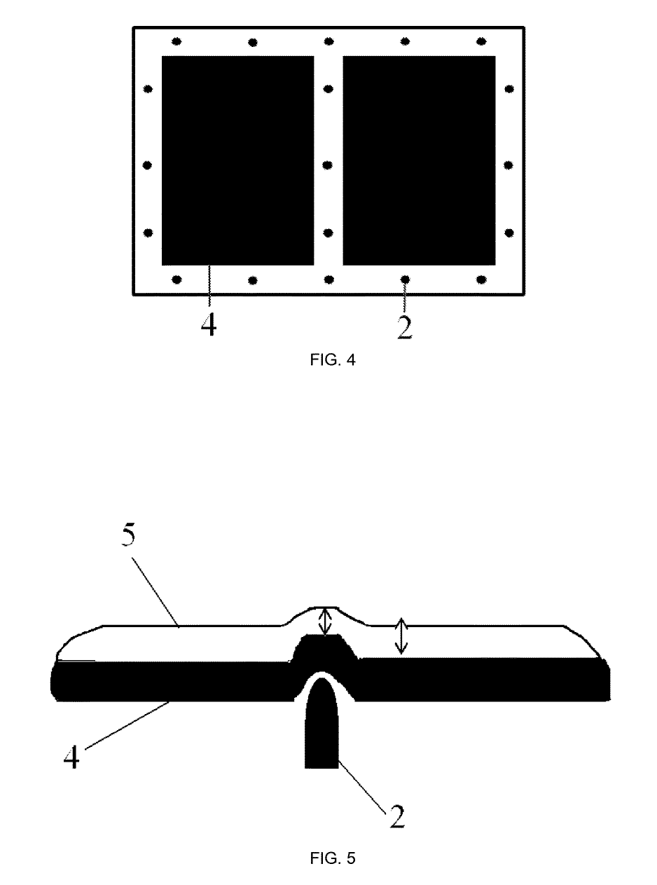

Wherein, 1: chamber; 2: support pin; 3: manipulator; 4: substrate; 5: film layer; 6: fixed mechanism; 61: table board; 611: sub-table board; 612: strip gap; 62: via-hole; 63: table pillar; 7: lifting mechanism; 71: flat plate part; 72: lifting driving unit; 73: support rod; 731: connection rod; 74: support pillar.

### DETAILED DESCRIPTION

The specific embodiments of the present invention will be described in detail as follows with reference to the accompanying drawings. It shall be appreciated that the embodiments described herein are only intended to illustrate and explain the present invention, rather than limit the same.

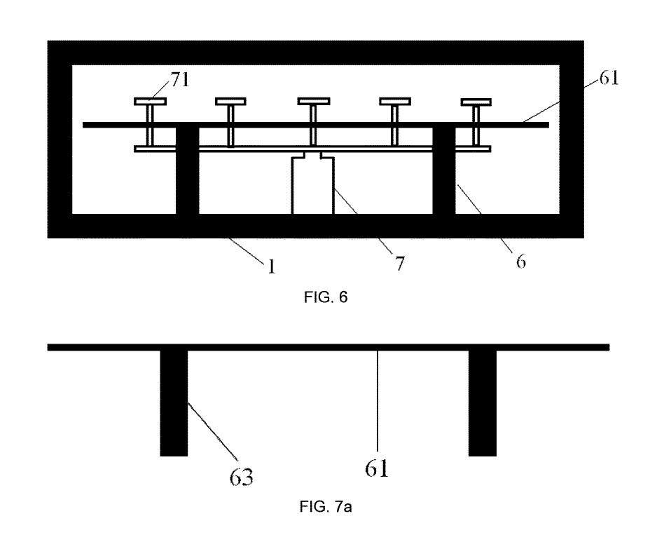

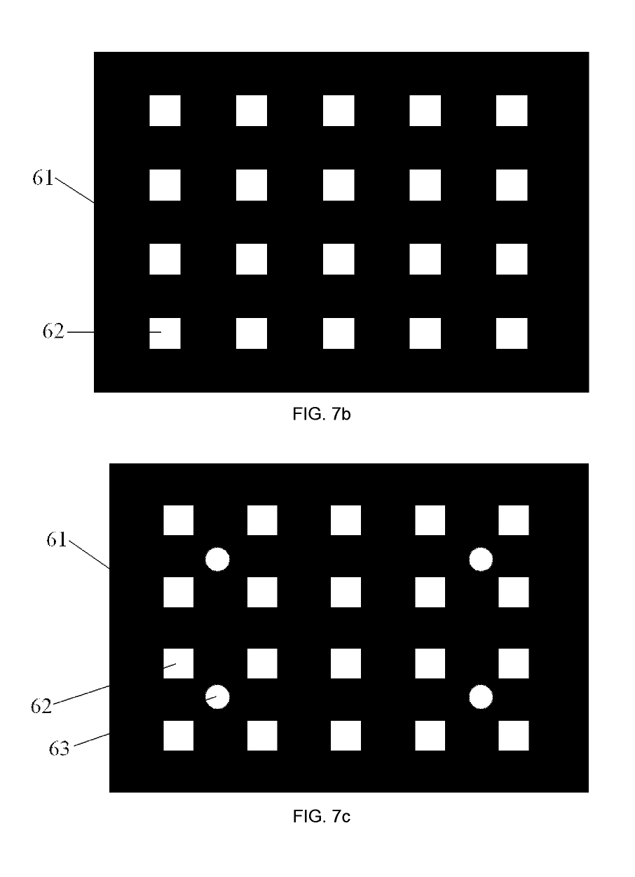

An embodiment of the present invention provides a substrate support device for a vacuum drying equipment. FIG. 6 is a structural diagram of a substrate support device according to a first embodiment of the present invention. The substrate support device comprises a fixed mechanism 6 and a lifting mechanism 7. The fixed mechanism 6 comprises a table board 61 arranged with a plurality of via-holes (as illustrated in FIG. 7b). The lifting mechanism 7 comprises a plurality of flat plate parts 71. The positions and shapes of the flat plate parts 71 are corresponding to those of the via-holes, thus those flat plate parts 71 are capable of moving into corresponding via-holes respectively to form a support surface for supporting the substrate, together with the table board 61. In this embodiment, the flat plate parts 71 are further capable of moving to positions above corresponding via-holes.

In the embodiment of the present invention, the substrate can be always placed on the flat table board throughout the drying process by way of cooperating the fixed mechanism 6 with the lifting mechanism 7. Thus, as compared with the prior art, the contact mode between the substrate and the substrate support device is changed from a point contact to a surface contact, thereby reducing the risk of the product display deficiency.

In addition, it is unnecessary to consider the substrate layout for different models of products. When the product model is changed, the support device needs not to be adjusted, thus the personal workload is reduced. Meanwhile, according to the embodiment of the present invention, it can be avoided that the particles are introduced into the equipment by any person when adjusting the support device, and the display deficiency due to a wrong support position caused by the human error can be prevented, thereby the product quality is improved. Regarding to the product design, since the contact mode is changed from the point contact to the surface contact, the positions of the contact points need not to be considered, thus the substrate can be sufficiently utilized, and the design difficulty is decreased.

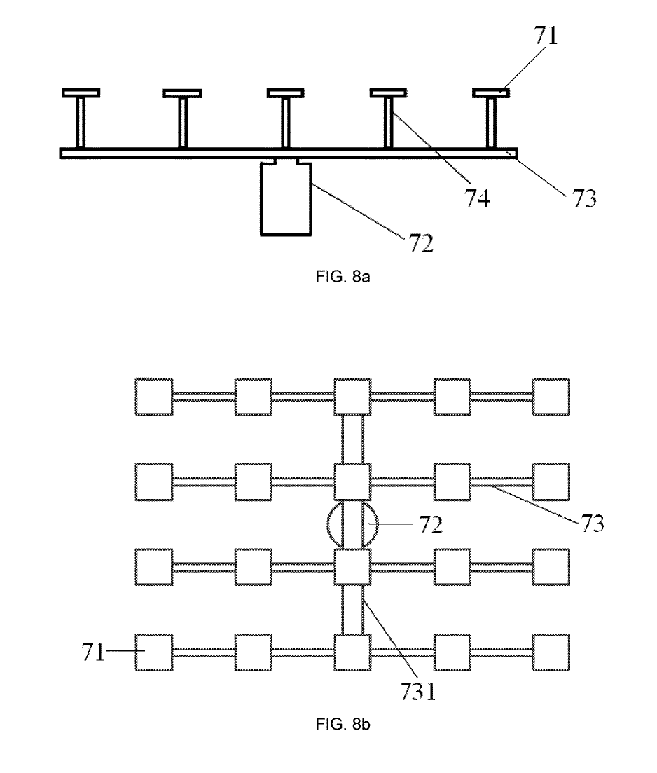

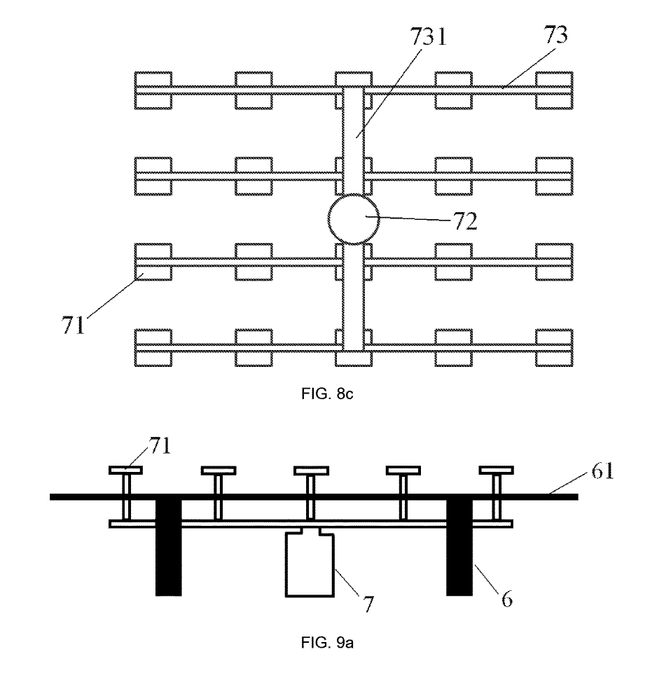

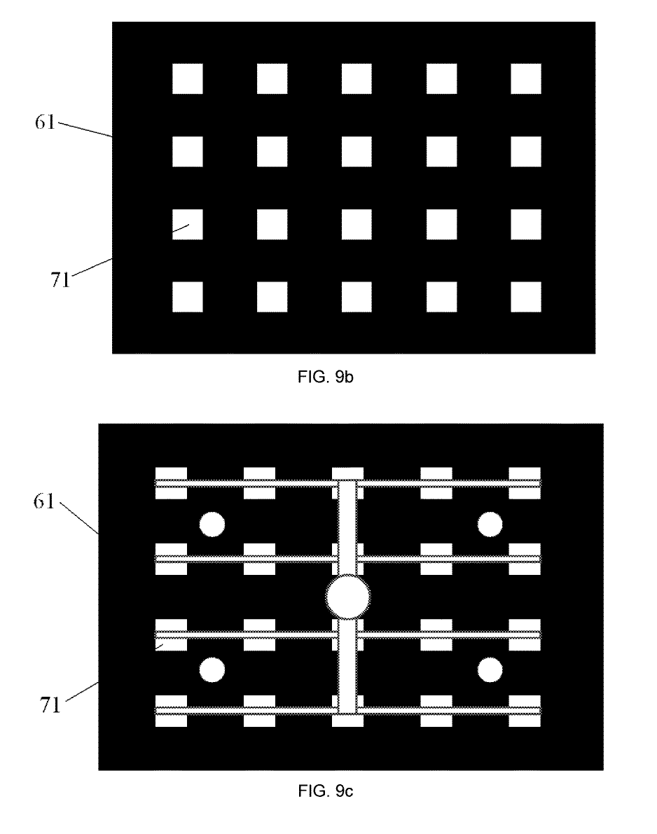

FIGS. 7a to 7c schematically illustrate the fixed mechanism 6 according to the first embodiment of the present invention, FIGS. 8a to 8c schematically illustrate the lifting mechanism 7 according to the first embodiment of the present invention, and FIGS. 9a to 9c schematically illustrate a combination of the fixed mechanism 6 and the lifting mechanism 7.

The substrate support device according to the first embodiment comprises a fixed mechanism 6 and a lifting mechanism 7. In the first embodiment of the present invention, the fixed mechanism 6 comprises via-holes 62 and a table board 61. The via-hole 62 has a closed shape and the plurality of via-holes 62 are uniformly distributed in the table board 61. The lifting mechanism 7 comprises a lifting driving unit 72, a plurality of horizontal support rods 73 and a plurality of vertical support pillars 74. Each support rod 73 is provided with several support pillars 74 for supporting the flat plate parts 71. The lifting driving unit 72 is arranged to drive the support rod 73 to rise and descend. The shape of the flat plate part 71 is matched with that of the via-hole 62 at corresponding position. Although the via-hole 62 and the flat plate part 71 are illustrated as being rectangular in the drawings, it is anticipated that they may have other shapes, such as circle, ellipse and polygon. In an embodiment, the via-hole 62 and the flat plate part 71 are shaped as rectangles or circles. The table board 61 is supported by a plurality of table pillars 63, and the bottom ends of the table pillars 63 are fixed on the bottom surface inside the chamber 1 of the vacuum drying equipment (referring to FIG. 6).

Further, the lifting mechanism 7 also comprises a connection rod 731 arranged to connect the plurality of support rods 73 together. The connection rod 731 is connected to an output shaft of the lifting driving unit 72. Namely, the driving force of the lifting driving unit 72 is output to the plurality of support rods 73 by driving the connection rod 731, so that the flat plate part 71 rises or descends. In the embodiments of the present invention, the lifting driving unit 72 may be a cylinder.

In an embodiment, as illustrated in FIG. 8b, the extending direction of the connection rod 731 is perpendicular to that of the support rod 73. The plurality of support rods 73 are uniformly distributed on the connection rod 731, thereby improving the balance of the support rod and the structural strength. In this embodiment, since the flat plate part 71 has a small area, each support pillar 74 may be arranged to support one flat plate part 71.

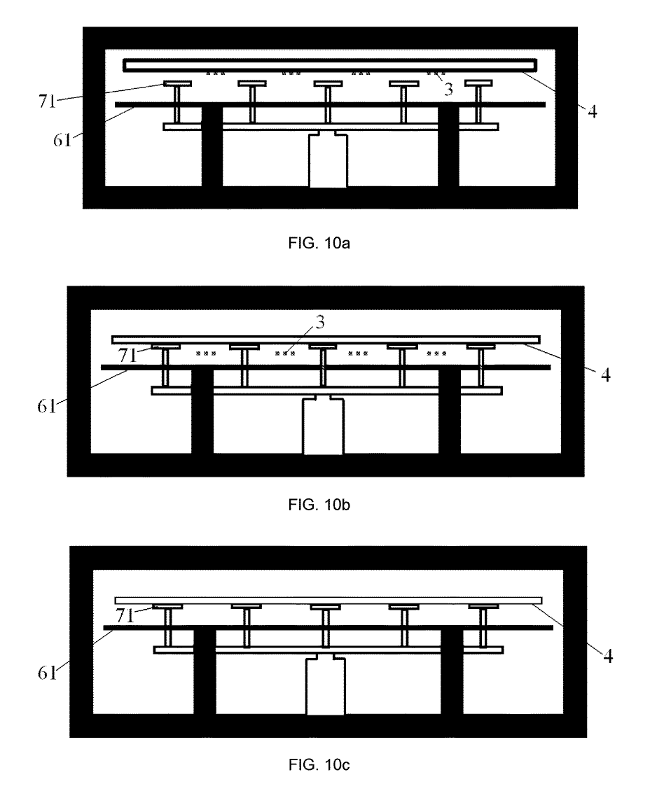

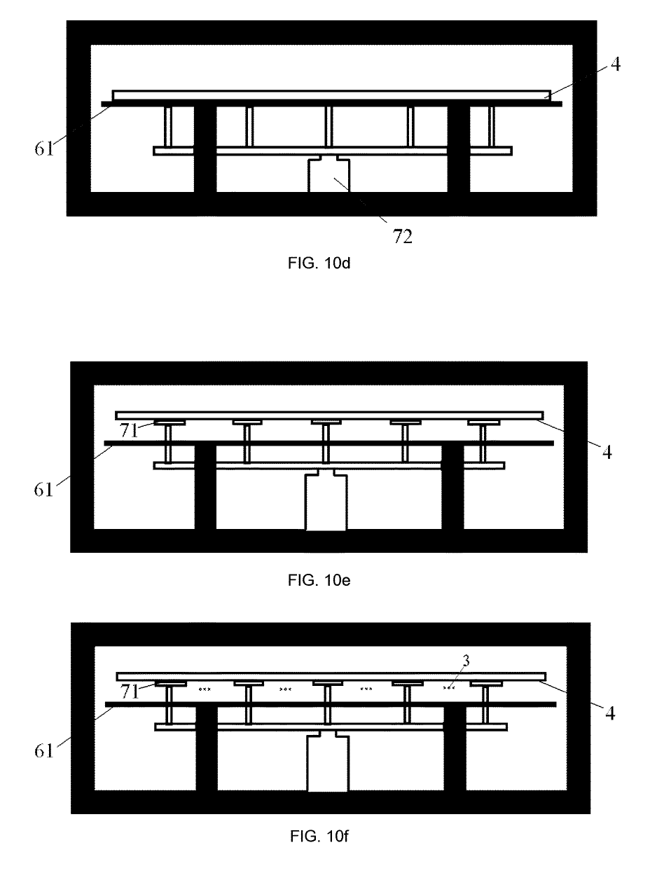

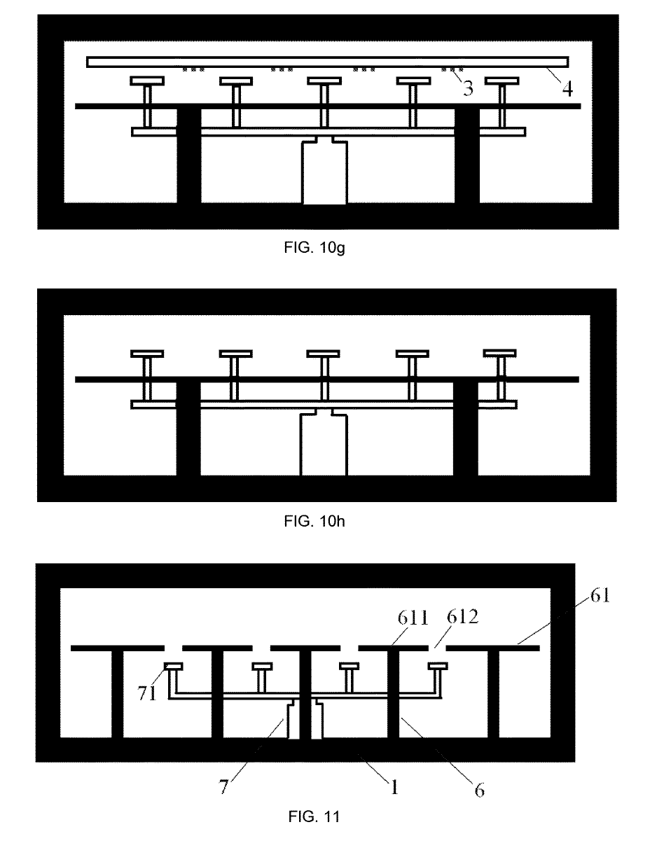

FIGS. 10a to 10h are flowcharts of the working process of the substrate support device according to the first embodiment. The specific steps comprise:

S11: as illustrated in FIG. 10a, arranging the substrate support device in an initial state so that the flat plate part 71 is higher than the table board 61, and then transferring the substrate 4 to a position above the substrate support device through the manipulator 3;

S12: as illustrated in FIG. 10b, lowering the manipulator 3, and placing the substrate 4 on the flat plate part 71;

S13: as illustrated in FIG. 10c, withdrawing the manipulator 3;

S14: as illustrated in FIG. 10d, the lifting driving unit 72 driving the flat plate part 71 to descend until the flat plate part 71 moves into the via-hole at corresponding position and is flushed with the table board 61; at that time, the substrate 4 located on a support surface formed by the flat plate part 71 and the table board 61 together, and then performing a vacuum drying treatment on the substrate 4;

S15: as illustrated in FIG. 10e, the lifting driving unit 72 driving the flat plate part 71 to rise when the drying treatment is completed, so that the substrate 4 is higher than the table board 61 after the drying treatment;

S16: as illustrated in FIG. 10f, the manipulator 3 moving to the below of the substrate, so that the manipulator 3 is located between the flat plate part 71 and the table board 61;

S17: as illustrated in FIG. 10g, the manipulator 3 rising so as to take out the substrate 4;

S18: as illustrated in FIG. 10h, recovering the substrate support device into the initial state.

In the drying process of the present invention, the substrate 4 is always supported by the horizontal table board 61 and the flat plate part 71 together. In addition, the gap between the table board 61 and the flat plate part 71 is preferably within 2 mm. The gap is small enough relative to the size of the substrate 4, and has no influence on the levelness of the substrate 4, thereby ensuring the product quality.

In the design of the substrate support device, the flat plate parts 71 and the via-holes 62 are uniformly distributed. The positions and sizes of the flat plate part 71 and the via-hole 62 may be configured by referring to the width of the manipulator 3 and the moving path (horizontal moving path and vertical moving path), provided that the movement (horizontal movement and vertical movement) of the manipulator 3 does not spatially interfere with the substrate support device.

Further, since the airstream inside the chamber is strong in the vacuum drying process, several clamping parts (not illustrated) may be arranged on a part of the table board 61 corresponding to the edge of the substrate 4, in order to prevent the substrate 4 from drifting on the table board 61. Before the substrate 4 is placed on the table board 61, the clamping part is in a released state. After the substrate 4 is placed on the table board 61, the clamping part may fix the substrate 4 on the table board 61 and keep it in a fixed state in the whole drying process. When the drying process is finished, the clamping part may be released again, so as to take off the substrate 4 from the table board 61.

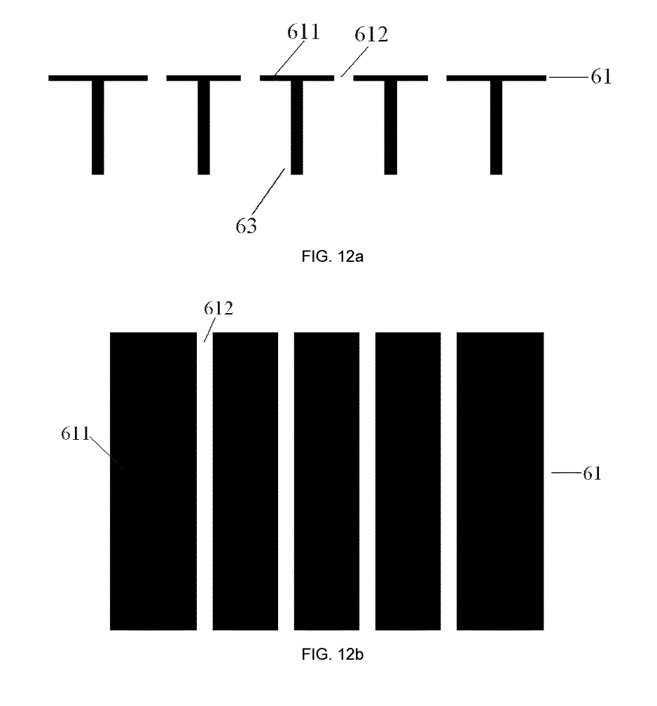

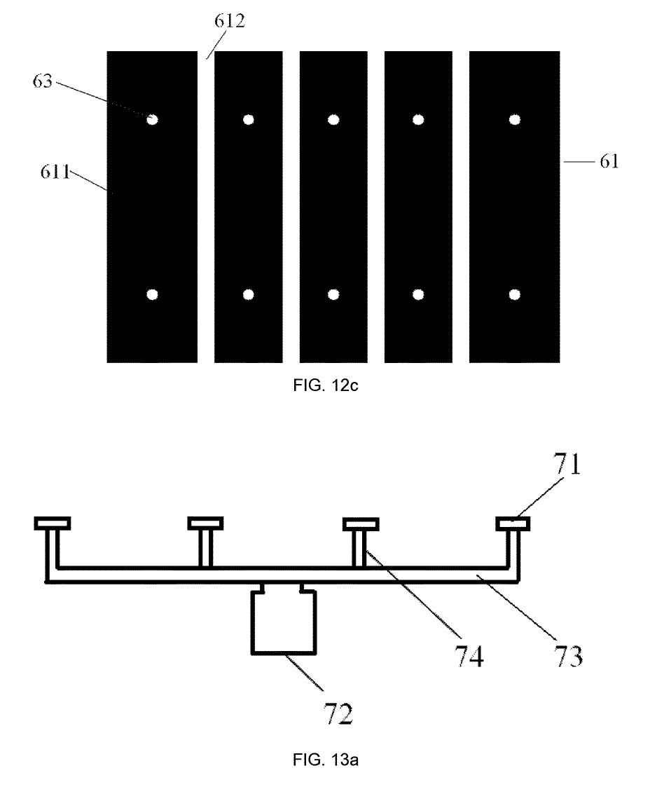

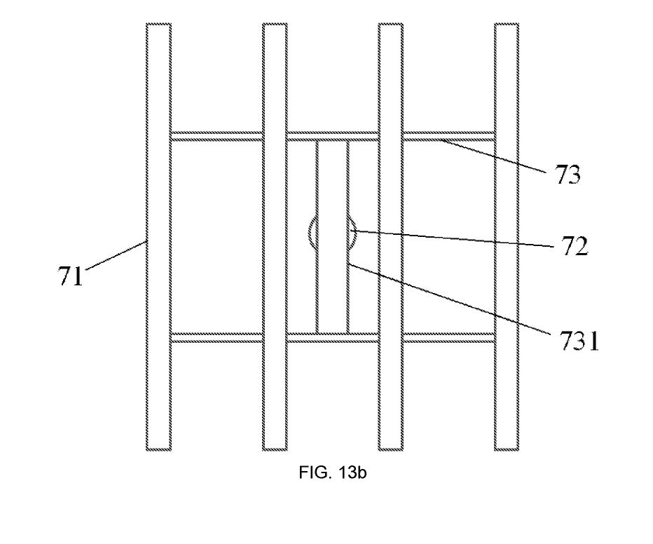

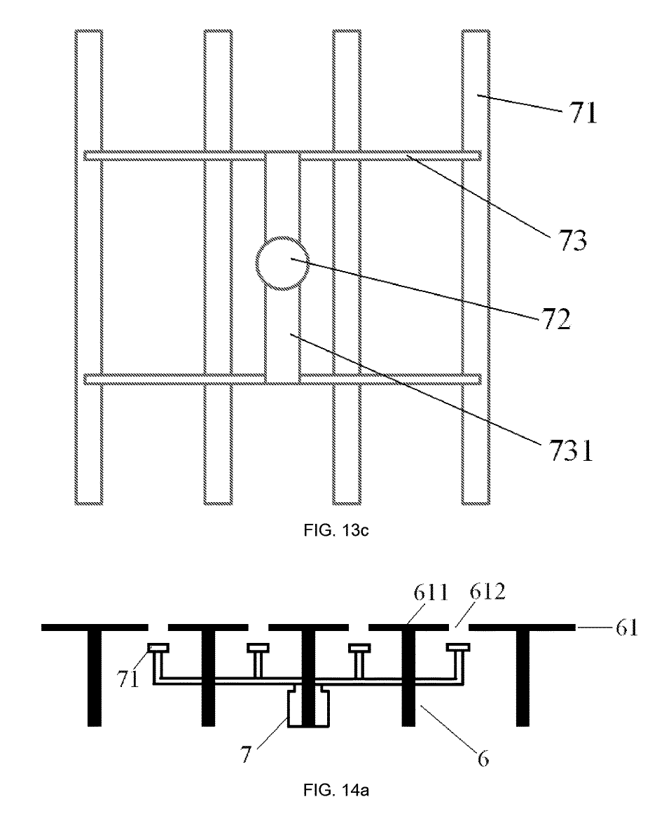

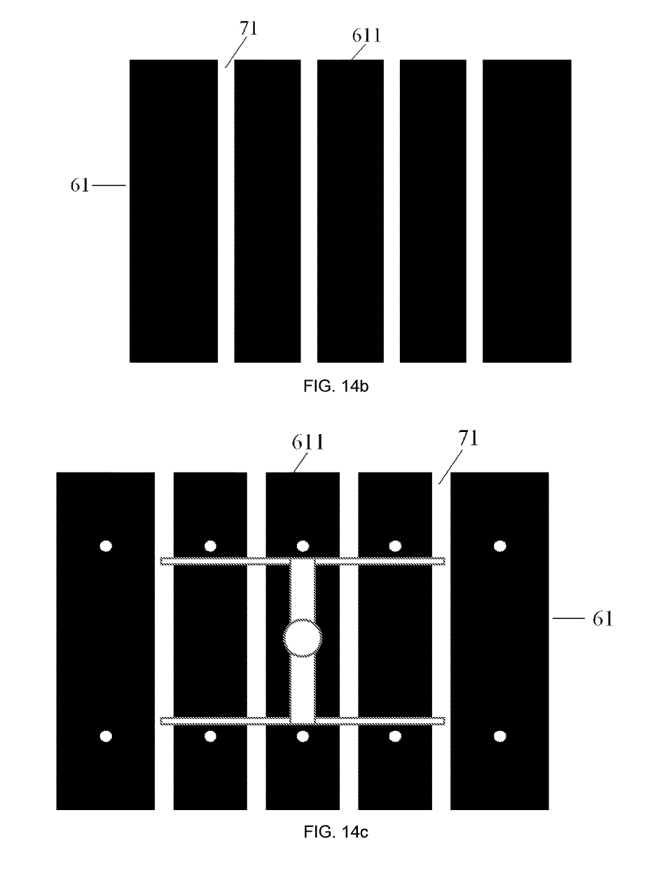

FIG. 11 schematically illustrates a substrate support device according to a second embodiment of the present invention. FIGS. 12a to 12c schematically illustrate a fixed mechanism 6 according to the second embodiment of the present invention, FIGS. 13a to 13c schematically illustrate a lifting mechanism 7 according to the second embodiment of the present invention, and FIGS. 14a to 14c schematically illustrate a combination of the fixed mechanism 6 and the lifting mechanism 7.

The substrate support device according to the second embodiment comprises a fixed mechanism 6 and a lifting mechanism 7. In the second embodiment of the present invention, the fixed mechanism 6 comprises a table board 61 comprising a plurality of sub-table boards 611. A strip gap 612 is formed between every two adjacent sub-table boards 611 (as clearly illustrated in FIG. 12b). The strip gap 612 in this embodiment is corresponding to the via-hole 62 in the first embodiment of the present invention.

In the second embodiment of the present invention, a plurality of strip gaps 612 are uniformly distributed in the table board 61, so as to divide the table board 61 into a plurality of sub-table boards 611. The shape of the flat plate part 71 is matched with that of the strip gap 612 at corresponding position. Each sub-table board 611 is supported by at least one table pillar 63. The bottom end of the table pillar 63 is fixed on the bottom surface inside the chamber 1 of the vacuum drying equipment (referring to FIG. 11).

It shall be illustrated that, in the second embodiment, the width of the strip gap 612 is preferably larger than that of the manipulator, so that the manipulator freely passes through the strip gap 612 during the rising and descending. Thus, the substrate support device can work more flexibly.

The lifting mechanism 7 comprises a lifting driving unit 72, a plurality of horizontal support rods 73 and a plurality of vertical support pillars 74. Each support rod 73 is provided with a support pillar 74 for supporting the flat plate part 71. The lifting driving unit 72 is arranged to drive the support rod 73 to rise and descend.

Further, the lifting mechanism 7 also comprises a connection rod 731 arranged to connect the plurality of support rods 73 together. The connection rod 731 is connected to an output shaft of the lifting driving unit 72. Namely, the driving force of the lifting driving unit 72 is output to the plurality of support rods 73 by driving the connection rod 731, so that the flat plate part 71 rises or descends. In the embodiments of the present invention, the lifting driving unit 72 may be a cylinder.

In an embodiment, as illustrated in FIG. 13b, the extending direction of the connection rod 731 is perpendicular to that of the support rod 73. The plurality of support rods 73 are uniformly distributed on the connection rod 731, thereby improving the balance of the support rod and the structural strength. In this embodiment, since the flat plate part 71 has a strip shape, the plurality of support pillars 74 located on the plurality of support rods 73 may be arranged to support one flat plate part 71 together.

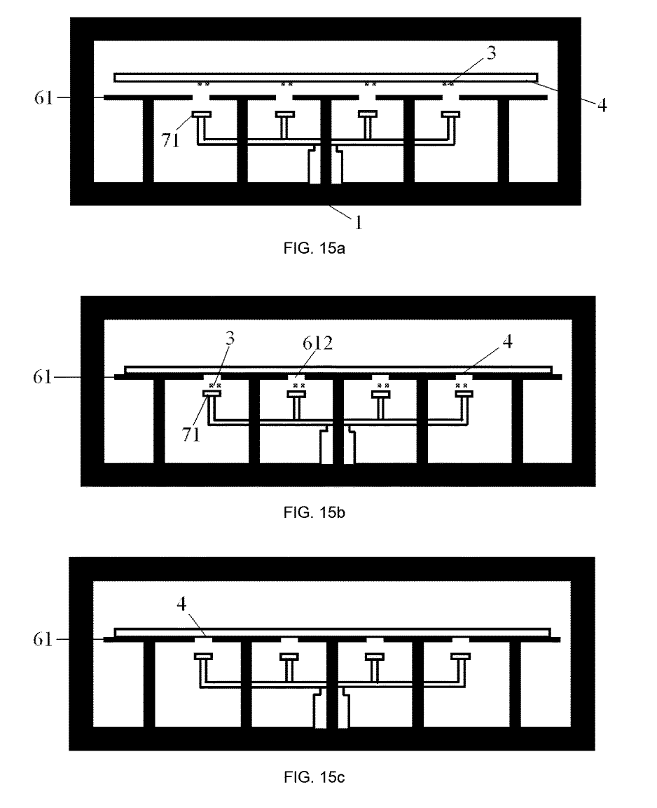

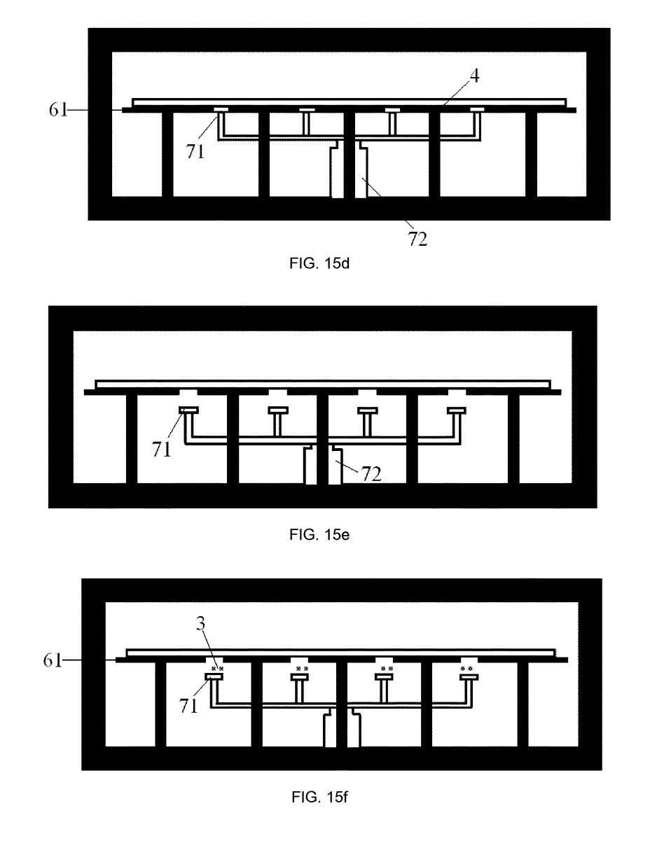

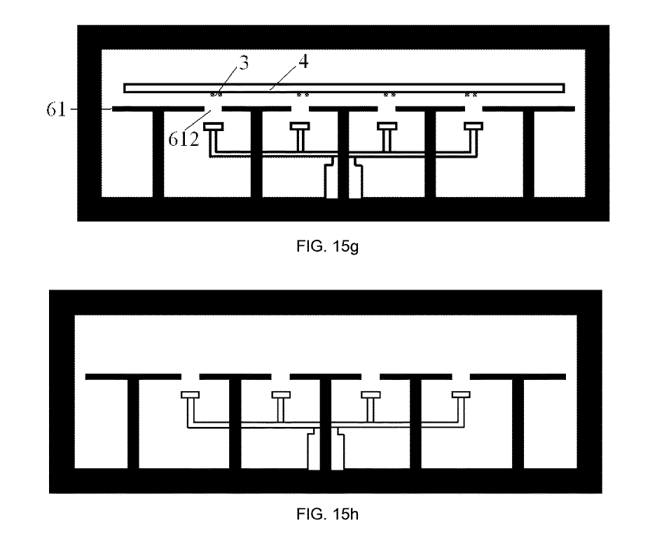

FIGS. 15a to 15h are flowcharts of the working process of the substrate support device according to the second embodiment. The specific steps comprise:

S21: as illustrated in FIG. 15a, arranging the substrate support device in an initial state so that the flat plate part 71 is lower than the table board 61, and then transferring the substrate 4 to a position above the substrate support device through the manipulator 3;

S22: as illustrated in FIG. 15b, lowering the manipulator 3, and placing the substrate 4 on the table board 61, wherein the manipulator 3 passes through the strip gap 612 in the descending process and stays between the table board 61 and the flat plate part 71;

S23: as illustrated in FIG. 15c, withdrawing the manipulator 3;

S24: as illustrated in FIG. 15d, the lifting driving unit 72 driving the flat plate part 71 to rise until the flat plate part 71 moves into the strip gap 612 and is flushed with the table board 61; at that time, the substrate 4 located on a support surface formed by the flat plate part 71 and the table board 61 together, and then performing a vacuum drying treatment on the substrate 4;

S25: as illustrated in FIG. 15e, the lifting driving unit 72 driving the flat plate part 71 to descend to an initial height when the drying treatment is completed;

S26: as illustrated in FIG. 15f, the manipulator 3 moves to a position corresponding to the strip gap 612 and between the table board 61 and the flat plate part 71;

S27: as illustrated in FIG. 15g, the manipulator 3 rising to take out the substrate 4;

S28: as illustrated in FIG. 15h, recovering the substrate support device into the initial state.

It shall be illustrated that, in the second embodiment, the flat plate part 71 may be initially located either above or below the table board 61. When the flat plate part 71 is initially located above the table board 61, the working flow is the same as that in the first embodiment, and it is not repeated herein.

In the drying process of the present invention, the substrate 4 is always supported by the horizontal table board 61 and the flat plate part 71 together. In addition, the gap between the table board 61 and the flat plate part 71 is preferably within 2 mm. The gap is small enough relative to the size of the substrate 4, and has no influence on the levelness of the substrate 4, thereby ensuring the product quality.

In the design of the substrate support device, the position and size of the flat plate part 71 may be configured by referring to the width of the manipulator 3 and the moving path (horizontal moving path and vertical moving path), provided that the movement (horizontal movement and vertical movement) of the manipulator 3 does not spatially interfere with the substrate support device.

Further, since the airstream inside the chamber is strong in the vacuum drying process, several clamping parts (not illustrated) may be arranged on a part of the table board 61 corresponding to the edge of the substrate 4, in order to prevent the substrate 4 from drifting on the table board 61. Before the substrate 4 is placed on the table board 61, the clamping part is in a released state. After the substrate 4 is placed on the table board 61, the clamping part may fix the substrate 4 on the table board 61 and keep it in a fixed state in the whole drying process. When the drying process is finished, the clamping part may be released again, so as to take off the substrate 4 from the table board 61.

The embodiment of the present invention further provides a support method using the above substrate support device, mainly comprising: when drying the substrate, moving the flat plate part of the lifting mechanism into the via-hole of the fixed mechanism, so as to support the substrate together with the table board of the fixed mechanism.

According to the embodiment of the present invention, the substrate is always placed on the flat table board throughout the drying process. Thus, as compared with the prior art, the contact mode between the substrate and the substrate support device is changed from a point contact to a surface contact, thereby reducing the risk of the product display deficiency.

As a first embodiment, the support method comprises:

before drying the substrate, disposing the flat plate part of the lifting mechanism above the via-hole of the fixed mechanism, and placing the substrate on the flat plate part;

when drying the substrate, lowering the flat plate part into the via-hole, so that the flat plate part is flushed with the table board of the fixed mechanism; and

after drying the substrate, raising the flat plate part to a position above the via-hole so as to take out the substrate.

As a second embodiment, the support method comprises:

before drying the substrate, disposing the flat plate part of the lifting mechanism below the via-hole of the fixed mechanism, and placing the substrate on the table board;

when drying the substrate, raising the flat plate part into the via-hole, so that the flat plate part is flushed with the table board of the fixed mechanism; and

after drying the substrate, lowering the flat plate part to a position below the via-hole so as to take out the substrate.

The embodiment of the present invention further provides a vacuum drying equipment comprising the substrate support device according to the embodiment of the present invention.

According to the embodiment of the present invention, the substrate is always placed on the flat table board throughout the drying process. Thus, as compared with the prior art, the contact mode between the substrate and the substrate support device is changed from a point contact to a surface contact, thereby reducing the risk of the product display deficiency. In addition, it is unnecessary to consider the substrate layout for different models of products. When the product model is changed, the support device needs not to be adjusted, thus the personal workload is reduced, and the design difficulty is decreased.

It shall be appreciated that the above embodiments are just exemplary ones adopted to describe the principle of the present invention, and the present invention is not limited thereto. A person skilled in the art can make various modifications and improvements without departing from the spirit and substance of the present invention, and the modifications and improvements are also deemed as falling within the protection scope of the present invention.

1. A substrate support device for a vacuum drying equipment, comprising a fixed mechanism that includes a table board arranged with a plurality of via-holes, and a lifting mechanism that includes a plurality of flat plate parts corresponding to the via-holes, the plurality of flat plate parts being capable of moving into corresponding via-holes respectively to form a support surface for supporting the substrate, together with the table board, and further capable of moving to positions above the corresponding via-holes.

2. The substrate support device according to claim 1, wherein the table board comprises a plurality of sub-table boards, and a strip gap is formed between every two adjacent sub-table boards to serve as a via-hole.

3. The substrate support device according to claim 1, wherein the via-hole has a closed shape.

4. The substrate support device according to claim 3, wherein the closed shape is rectangular or circular.

5. The substrate support device according to claim 1, wherein the plurality of via-holes are uniformly distributed in the table board, and the shape of the flat plate part is matched with that of the via-hole at corresponding position.

6. The substrate support device according to claim 1, wherein the lifting mechanism comprises a lifting driving unit, a plurality of support rods and a plurality of support pillars, each of the support rods is arranged with a support pillar for supporting the flat plate part, and the lifting driving unit is arranged to drive the support rods to rise and descend.

7. The substrate support device according to claim 6, wherein the lifting mechanism further comprises a connection rod for connecting the plurality of support rods together, and the connection rod is connected to an output shaft of the lifting driving unit.

8. The substrate support device according to claim 6, wherein each of the support pillars supports one of the flat plate parts separately or
wherein several of the support pillars support one of the flat plate parts together.

9. (canceled)

10. A support method using the substrate support device according to claim 1, comprising:
when drying the substrate, moving the flat plate part of the lifting mechanism into the via-hole of the fixed mechanism, so as to support the substrate together with the table board of the fixed mechanism.

11. The support method according to claim 10, comprising:
before drying the substrate, moving the flat plate part of the lifting mechanism to a position above the via-hole of the fixed mechanism, and placing the substrate on the flat plate part;
when drying the substrate, lowering the flat plate part into the via-hole, so that the flat plate part is flushed with the table board of the fixed mechanism; and
after drying the substrate, raising the flat plate part to a position above the via-hole so as to take out the substrate.

12. The support method according to claim 10, comprising:
before drying the substrate, moving the flat plate part of the lifting mechanism to a position below the via-hole of the fixed mechanism, and placing the substrate on the table board;
when drying the substrate, raising the flat plate part into the via-hole, so that the flat plate part is flushed with the table board of the fixed mechanism; and
after drying the substrate, lowering the flat plate part to a position below the via-hole so as to take out the substrate.

13. A vacuum drying equipment, comprising the substrate support device according to claim 1.

14. The substrate support device according to claim 2, wherein the plurality of via-holes are uniformly distributed in the table board, and the shape of the flat plate part is matched with that of the via-hole at corresponding position.

15. The substrate support device according to claim 2, wherein the lifting mechanism comprises a lifting driving unit, a plurality of support rods and a plurality of support pillars, each of the support rods is arranged with a support pillar for supporting the flat plate part, and the lifting driving unit is arranged to drive the support rods to rise and descend.

16. The vacuum drying equipment according to claim 13, wherein the table board comprises a plurality of sub-table boards, and a strip gap is formed between every two adjacent sub-table boards to serve as a via-hole.

17. The vacuum drying equipment according to claim 13, wherein the via-hole has a closed shape.

18. The vacuum drying equipment according to claim 13, wherein the plurality of via-holes are uniformly distributed in the table board, and the shape of the flat plate part is matched with that of the via-hole at corresponding position.

19. The vacuum drying equipment according to claim 13, wherein the lifting mechanism comprises a lifting driving unit, a plurality of support rods and a plurality of support pillars, each of the support rods is arranged with a support pillar for supporting the flat plate part, and the lifting driving unit is arranged to drive the support rods to rise and descend.

20. The vacuum drying equipment according to claim 19, wherein the lifting mechanism further comprises a connection rod for connecting the plurality of support rods together, and the connection rod is connected to an output shaft of the lifting driving unit.

21. The vacuum drying equipment according to claim 19, wherein each of the support pillars supports one of the flat plate parts separately, or
wherein several of the support pillars support one of the flat plate parts together.
